(19) United States
(12) Patent Application Publication
(10) Pub. No.: US 2026/0068079 A1
(43) Pub. Date: Mar. 5, 2026

(54) ELECTRONIC DEVICE

(71) Applicant: HTC Corporation, Taoyuan City (TW)

(72) Inventors: Li-Hsun Chang, Taoyuan City (TW); Pei Chia Lee, Taoyuan City (TW); Chih-Hsiang Hsieh, Taoyuan City (TW)

(73) Assignee: HTC Corporation, Taoyuan City (TW)

(21) Appl. No.: 19/096,733

(22) Filed: Apr. 1, 2025

Related U.S. Application Data
(60) Provisional application No. 63/690,287, filed on Sep. 3, 2024.

(51) Int. Cl. H05K 7/20; H05K 5/02

(52) U.S. Cl. CPC H05K 7/20172; H05K 5/0213

(57) ABSTRACT

An electronic device comprises a housing, a first heat source, a second heat source and a fan. The housing has a first chamber, a second chamber, a first air inlet, a second air inlet, a first air outlet, and a second air outlet. The first air inlet and the first air outlet communicate with the first chamber. The second air inlet and the second air outlet communicate with the second chamber. The first air outlet is adjacent to the second air outlet. The second heat source is disposed in the first chamber and is partially exposed to the second chamber. The fan is disposed in the first chamber for generating a first airflow that enters from the first air inlet, passes through the first heat source, and exits through the first air outlet. When the first airflow exits through the first air outlet, a second airflow is induced that enters from the second air inlet, passes through the portion of the second heat source exposed to the second chamber, and exits through the second air outlet.

### CROSS-REFERENCE TO RELATED APPLICATION

This application claims the priority benefit of U.S. provisional application Ser. No. 63/690,287, filed on Sep. 3, 2024. The entirety of the above-mentioned patent application is hereby incorporated by reference herein and made a part of this specification.

### BACKGROUND

### Technical Field

The disclosure relates to a device, and in particular relates to an electronic device.

### Description of Related Art

Conventional heat dissipation methods for electronic devices generally collect heat from a primary heat source through a heat pipe to a heat dissipation fin, and then actively dissipate heat through an airflow generated by a fan. However, in addition to the primary heat source, there are often other secondary heat sources in electronic devices that also require heat dissipation. Without increasing the number of fans, passive heat dissipation methods are generally employed to manage the heat generated by these secondary heat sources. For instance, copper foil or graphite sheets may be affixed to secondary heat sources to conduct the heat to the surface of the device, and then the heat is dissipated by heat convection from the external air. However, compared with active heat dissipation, passive heat dissipation exhibits inferior heat dissipation effect.

### SUMMARY

An electronic device is provided in this application, in which the electronic device may improve the problem of poor heat dissipation effect associated with passive heat dissipation.

An electronic device of the present application includes a housing, a first heat source, a second heat source, and a fan. The housing has a first chamber, a second chamber, a first air inlet, a second air inlet, a first air outlet, and a second air outlet. The first chamber and the second chamber are independent of each other. The first air inlet and the first air outlet communicate with the first chamber. The second air inlet and the second air outlet communicate with the second chamber. The first air outlet is adjacent to the second air outlet. The first heat source is disposed in the first chamber. The second heat source is disposed in the first chamber and is partially exposed to the second chamber. The fan is disposed in the first chamber for generating a first airflow that enters from the first air inlet, passes through the first heat source, and exits through the first air outlet. When the first airflow exits through the first air outlet, a second airflow is induced that enters from the second air inlet, passes through a portion of the second heat source exposed to the second chamber, and exits through the second air outlet.

Based on the above, in the electronic device of the present application, the second airflow induced by the first airflow may actively dissipate heat for the second heat source, thus achieving a better heat dissipation effect.

### BRIEF DESCRIPTION OF THE DRAWINGS

FIG. 1 is a schematic diagram of the appearance of an electronic device according to an embodiment of the invention.

FIG. 2 is a partial cross-sectional diagram of the electronic device of FIG. 1.

FIG. 3 is a partial cross-sectional diagram of an electronic device according to another embodiment of the invention.

FIG. 4 is a partial schematic diagram of an electronic device according to yet another embodiment of the invention.

FIG. 5 is a schematic diagram of the appearance of an electronic device according to yet another embodiment of the invention.

### DETAILED DESCRIPTION OF DISCLOSED EMBODIMENTS

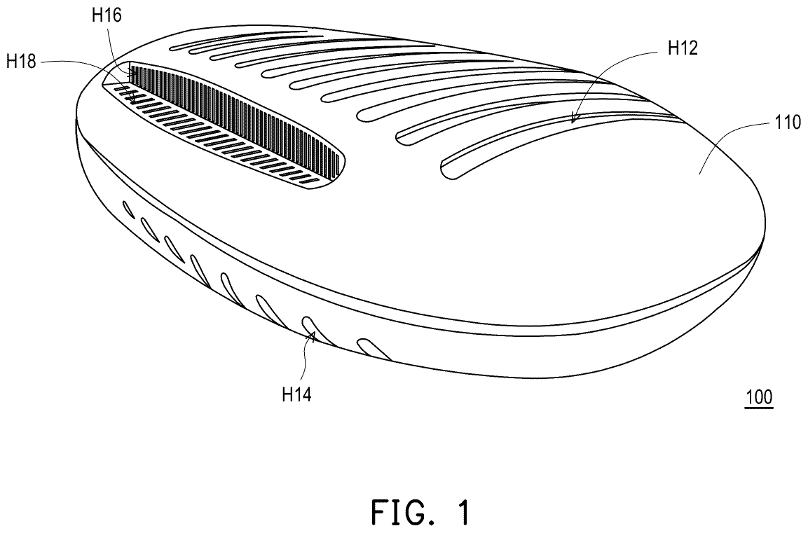

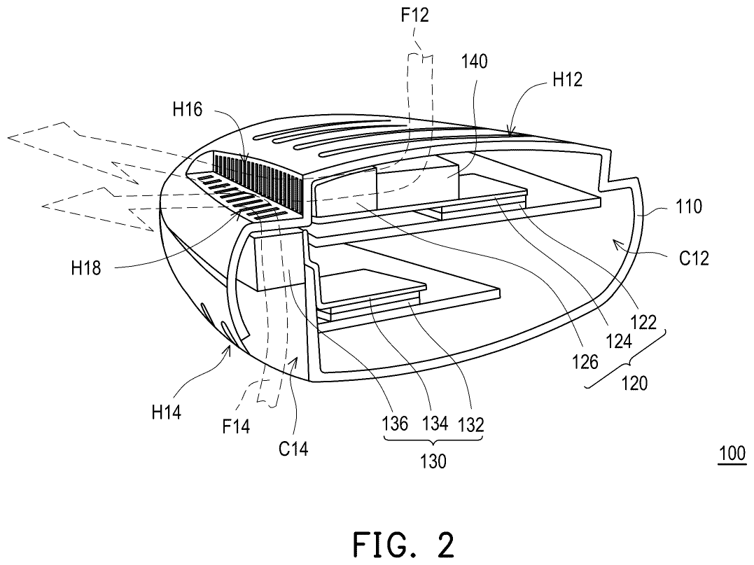

FIG. 1 is a schematic diagram of the appearance of an electronic device according to an embodiment of the invention. FIG. 2 is a partial cross-sectional diagram of the electronic device of FIG. 1. Referring to FIG. 1 to FIG. 2, the electronic device 100 of this embodiment includes a housing 110, a first heat source 120, a second heat source 130, and a fan 140. The housing 110 has a first chamber C12, a second chamber C14, a first air inlet H12, a second air inlet H14, a first air outlet H16, and a second air outlet H18. The first chamber C12 and the second chamber C14 are independent of each other. That is, there is basically no convection between the air in the first chamber C12 and the air in the second chamber C14, but this does not mean that the first chamber C12 and the second chamber C14 are completely hermetically separated from each other. The first air inlet H12 and the first air outlet H16 communicate with the first chamber C12. The second air inlet H14 and the second air outlet H18 communicate with the second chamber C14. The first air outlet H16 is adjacent to the second air outlet H18, so the airflow exiting the first air outlet H16 flows past the second air outlet H18 and creates a disturbance the airflow in the second chamber C14. In other words, whether the first air outlet H16 and the second air outlet H18 are adjacent is also related to the flow velocity and flow rate of the airflow exiting the first air outlet H16. When the airflow exiting the first air outlet H16 has a higher flow velocity and greater flow rate, the distance between the first air outlet H16 and the second air outlet H18 may be greater while still generating a disturbance in the airflow within the second chamber C14.

The first heat source 120 and the second heat source 130 are both disposed in the first chamber C12. Although the second heat source 130 is disposed in the first chamber C12, a portion of the second heat source 130 is exposed to the second chamber C14. The fan 140 is disposed in the first chamber C12 for generating a first airflow F12 that enters from the first air inlet H12, passes through the first heat source 120, and exits through the first air outlet H16. That is, the fan 140 may generate the first airflow F12, and the first airflow F12 passes through the first heat source 120 to produce an active heat dissipation effect on the first heat source 120.

When the first airflow F12 exits the first air outlet H16, a relatively low pressure environment is generated in the vicinity of the first air outlet H16. Therefore, the air in the adjacent second air inlet H14 is drawn by the low pressure and flows outward from the second chamber C14. That is, the first airflow F12 induces a second airflow F14. In other words, when the flow velocity of the first airflow F12 is higher, the flow velocity of the second airflow F14 also increases accordingly. The second airflow F14 enters the second chamber C14 from the second air inlet H14, passes through a portion of the second heat source 130 exposed to the second chamber C14, and exits through the second air outlet H18.

In the electronic device 100 of this embodiment, the fan 140 is only disposed in the first chamber C12 for active heat dissipation. However, by utilizing the design that the first air outlet H16 is adjacent to the second air outlet H18, a second airflow F14 may also be generated in the second chamber C14 to achieve an active heat dissipation effect. Therefore, the heat dissipation efficiency may be improved without increasing the number of fans 140, and the problems of increased cost and increased volume caused by increasing the number of fans 140 may also be avoided.

In this embodiment, the portion of the housing 110 having the first air outlet H16 may be perpendicular to the portion of the housing 110 having the second air outlet H18. That is, the air outlet surface of the first air outlet H16 is perpendicular to the air outlet surface of the second air outlet H18. In this way, the first airflow F12 has a better pulling effect on the second airflow F14, and no wind pressure is generated in the direction from the second air outlet H18 toward the interior of the second chamber C14.

In this embodiment, the first heat source 120 includes a first heat generating element 122, a first heat conducting element 124 and a first heat dissipation fin 126. The first heat conducting element 124 is thermally connected to the first heat generating element 122 and the first heat dissipation fin 126. The first airflow F12 passes through the first heat dissipation fin 126. That is, the heat generated by the first heat generating element 122 may be transferred to a location suitable for disposing the first heat dissipation fin 126 via the first heat conducting element 124, and then the heat transferred to the first heat dissipation fin 126 is taken away by the first airflow F12. The first heat generating element 122 may be a central processing unit or other element with a relatively high heat generation in an electronic device. Since the fan 140 directly generates the first airflow F12 to dissipate heat from the first heat generating element 122, it may better ensure that the first heat generating element 122 obtains sufficient heat dissipation efficiency and maintains normal operation. The first heat conducting element 124 includes, for example, at least one of a heat conducting block, a copper foil, a heat pipe, a graphene sheet, or other suitable heat conducting elements.

In this embodiment, the second heat source 130 includes a second heat generating element 132, a second heat conducting element 134 and a second heat dissipation fin 136. The second heat conducting element 134 is thermally connected to the second heat generating element 132 and the second heat dissipation fin 136. The second heat dissipation fin 136 is exposed to the second chamber C14. The second airflow F14 passes through the second heat dissipation fin 136. That is, the heat generated by the second heat generating element 132 may be transferred to a location suitable for disposing the second heat dissipation fin 136 via the second heat conducting element 134, and then the heat transferred to the second heat dissipation fin 136 is taken away by the first airflow F12. Specifically, the second heat dissipation fin 136 of this embodiment is located in the second chamber C14. The second heat generating element 132 may be a photosensitive and imaging chip or other element in an electronic device that generates relatively little heat. Although the first airflow F12 directly generated by the fan 140 cannot dissipate heat from the second heat generating element 132, the second airflow F14 induced by the first airflow F12 may actively dissipate heat from the second heat dissipation fin 136, ensuring that the second heat generating element 132 obtains sufficient heat dissipation efficiency and maintains normal operation. The second heat conducting element 134 includes, for example, at least one of a heat conducting block, a copper foil, a heat pipe, a graphene sheet, or other suitable heat conducting elements.

In this embodiment, the first heat generating element 122 of the first heat source 120 and the second heat generating element 132 of the second heat source 130 are respectively disposed on different circuit boards, but the present application is not limited thereto. In addition, the first heat dissipation fin 126 of the first heat source 120 and the second heat dissipation fin 136 of the second heat source 130 are independent of each other, but the present application is not limited thereto.

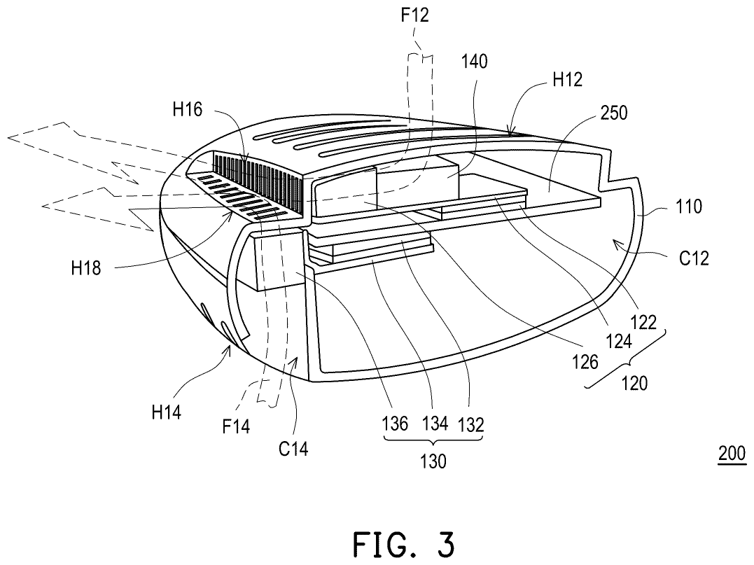

FIG. 3 is a partial cross-sectional diagram of an electronic device according to another embodiment of the invention. Referring to FIG. 3, the electronic device 200 of this embodiment is substantially the same as the electronic device 100 of FIG. 2, with the difference being that the electronic device 200 of this embodiment further includes a circuit board 250. Furthermore, the first heat generating element 122 of the first heat source 120 and the second heat generating element 132 of the second heat source 130 are both disposed on the same circuit board 250. For example, the first heat generating element 122 of the first heat source 120 and the second heat generating element 132 of the second heat source 130 may be disposed on different surfaces of the circuit board 250, but the present application is not limited thereto.

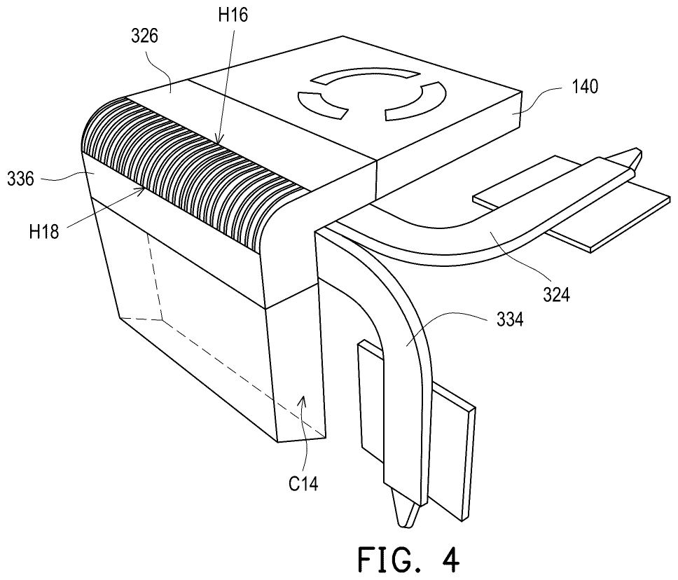

FIG. 4 is a partial schematic diagram of an electronic device according to yet another embodiment of the invention. Referring to FIG. 4, FIG. 4 only shows the second chamber C14, the fan 140, the first heat conducting element 324 of the first heat source, the second heat conducting element 334 of the second heat source, the first heat dissipation fin 326 of the first heat source, and the second heat dissipation fin 336 of the second heat source of the electronic device of this embodiment. The electronic device of this embodiment is substantially the same as the electronic device 100 of FIG. 2, with the difference being that in this embodiment, the second heat dissipation fin 336 of the second heat source exposed to the second chamber C14 is integrally formed with the first heat dissipation fin 326 of the first heat source. In this way, the assembly process may be simplified and the assembly accuracy may be improved. In this embodiment, the first air outlet and the second air outlet are still adjacent to each other, but are hidden in the second heat dissipation fin 336 and the first heat dissipation fin 326, that is, they are integrated into a common air outlet of the second heat dissipation fin 336 and the first heat dissipation fin 326. Likewise, in the above embodiments, the first air inlet and the second air inlet are independent of each other. However, in other embodiments, the first air inlet and the second air inlet may also be combined together, so the appearance is relatively simple.

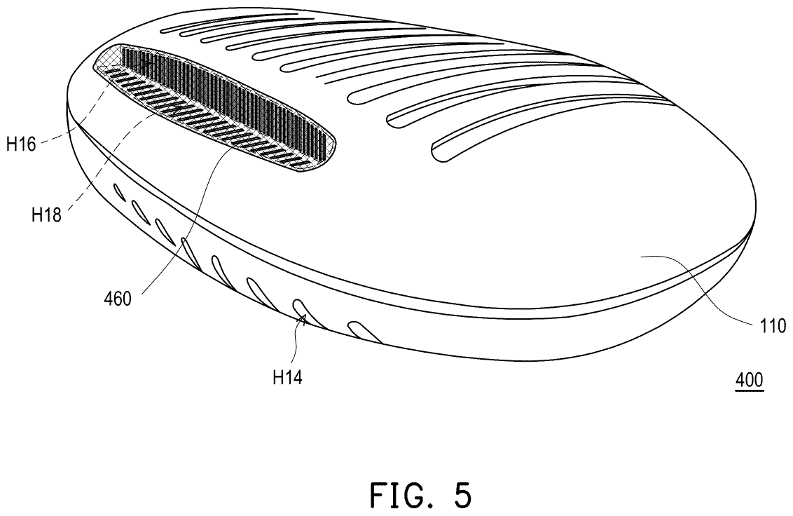

FIG. 5 is a schematic diagram of the appearance of an electronic device according to yet another embodiment of the invention. Referring to FIG. 5, the electronic device 200 of this embodiment is substantially the same as the electronic device 100 of FIG. 2, with the difference being that the electronic device 400 of this embodiment further includes a shielding net 460 disposed on the housing 110 and shielding the first air outlet H16 and the second air outlet H18. In this way, the electronic device 400 may have a more complete appearance.

In summary, in the electronic device of the present application, the first air outlet of the first chamber is adjacent to the second air outlet of the second chamber. The first airflow generated by the fan may actively dissipate heat from the first heat source 120, and the first airflow may also induce a second airflow to actively dissipate heat from the second heat source. Therefore, heat may be actively dissipated from two heat sources without the need for additional fans. The electronic device of the present application has the advantages of good heat dissipation effect, low cost and small volume.

What is claimed is:

1. An electronic device, comprising:
a housing, having a first chamber, a second chamber, a first air inlet, a second air inlet, a first air outlet, and a second air outlet, wherein the first chamber and the second chamber are independent of each other, the first air inlet and the first air outlet communicate with the first chamber, the second air inlet and the second air outlet communicate with the second chamber, the first air outlet is adjacent to the second air outlet;
a first heat source, disposed in the first chamber;
a second heat source, disposed in the first chamber and partially exposed to the second chamber; and
a fan, disposed in the first chamber for generating a first airflow that enters from the first air inlet, passes through the first heat source, and exits through the first air outlet, wherein when the first airflow exits through the first air outlet, a second airflow is induced that enters from the second air inlet, passes through a portion of the second heat source exposed to the second chamber, and exits through the second air outlet.

2. The electronic device according to claim 1, wherein a portion of the housing having the first air outlet is perpendicular to a portion of the housing having the second air outlet.

3. The electronic device according to claim 1, wherein the first heat source comprises a first heat generating element, a first heat conducting element and a first heat dissipation fin, the first heat conducting element is thermally connected to the first heat generating element and the first heat dissipation fin, the first airflow passes through the first heat dissipation fin.

4. The electronic device according to claim 3, wherein the first heat conducting element comprises at least one of a heat conducting block, a copper foil, and a heat pipe.

5. The electronic device according to claim 3, wherein the portion of the second heat source exposed to the second chamber is integrally formed with the first heat dissipation fin.

6. The electronic device according to claim 1, wherein the second heat source comprises a second heat generating element, a second heat conducting element and a second heat dissipation fin, the second heat conducting element is thermally connected to the second heat generating element and the second heat dissipation fin, the second heat dissipation fin is exposed to the second chamber, the second airflow passes through the second heat dissipation fin.

7. The electronic device according to claim 5, wherein the second heat conducting element comprises at least one of a heat conducting block, a copper foil, and a heat pipe.

8. The electronic device according to claim 1, further comprising a circuit board, wherein the first heat source and the second heat source are disposed on the circuit board.

9. The electronic device according to claim 1, further comprising a shielding net, disposed on the housing and shielding the first air outlet and the second air outlet.

10. The electronic device according to claim 1, wherein the first air inlet and the second air inlet are combined together.
